(19) United States
(12) Patent Application Publication
(10) Pub. No.: US 2024/0355652 A1
(43) Pub. Date: Oct. 24, 2024

(54) EFEM

(71) Applicant: Sinfonia Technology Co., Ltd., Tokyo (JP)

(72) Inventors: Gengoro Ogura, Tokyo (JP); Toshihiro Kawai, Tokyo (JP)

(73) Assignee: Sinfonia Technology Co., Ltd., Tokyo (JP)

(21) Appl. No.: 18/643,387

(22) Filed: Apr. 23, 2024

(30) Foreign Application Priority Data
Apr. 24, 2023 (JP) 2023-071090

(51) Int. Cl. H01L 21/67

(52) U.S. Cl. CPC H01L 21/67196

(57) ABSTRACT

An EFEM includes: a housing including a transfer chamber where a processing object is transferred; and a connection module provided between the transfer chamber and a front chamber of a processing apparatus configured to perform a predetermined process on the processing object, and connect the transfer chamber and the front chamber, wherein the housing includes a rear member formed with a housing side opening through which the processing object is capable of passing, wherein the connection module includes: a first connection member arranged around the housing side opening when viewed from a depth direction in which the housing and the front chamber are arranged, and attached to the rear member; and a second connection member arranged around a front chamber side opening formed in the front chamber so as to allow the processing object to pass therethrough when viewed from the depth direction, and attached to the front chamber.

### CROSS-REFERENCE TO RELATED APPLICATION

This application is based upon and claims the benefit of priority from Japanese Patent Application No. 2023-071090, filed on Apr. 24, 2023, the entire contents of which are incorporated herein by reference.

### TECHNICAL FIELD

The present disclosure relates to an equipment front end module (EFEM).

### BACKGROUND

Patent Document 1 discloses an interface (hereinafter referred to as a connection module) for connecting an equipment front end module (EFEM) and a load lock assembly (hereinafter referred to as a front chamber) provided in an electronic device processing system. More specifically, the EFEM and the front chamber are arranged side by side in a predetermined depth direction. Further, the connection module includes a plate-shaped attachment member and a bellows-shaped flexible sealing member. The attachment member is connected to the front chamber. The flexible sealing member is connected to and arranged around the attachment member. The flexible sealing member includes a sealing flange configured to seal around an opening within the EFEM. The sealing flange is fixed to an outer wall of the EFEM by a frame-like clamp.

In the above-described connection module, a positional relationship in the depth direction between the attachment member and the sealing flange may be adjusted by the flexible sealing member. Therefore, even in a case where a positional deviation between the EFEM and the front chamber in the depth direction is large due to a design error, the positional deviation is permitted to some extent.

### PRIOR ART DOCUMENT

### Patent Document

Patent Document 1: Japanese Patent No. 6882467

The connection module described above has a complex and extensive structure in which the flexible sealing member is provided around the attachment member, and the sealing flange of the flexible sealing member is fixed to the EFEM by the clamp. This may cause various problems. For example, since the attachment member is provided so as to hang from the flexible sealing member, it is necessary to support the attachment member by the members constituting the front chamber. For this reason, a weight of the attachment member increases load on the members that constitute the front chamber. Therefore, the members constituting the front chamber need to have a certain level of strength. As a result, a degree of freedom in designing the front chamber is reduced.

### SUMMARY

The present disclosure provides an EFEM capable of adjusting a position of a connection module with a simple structure.

According to a first aspect of the present disclosure, an EFEM includes: a housing including a transfer chamber in which a processing object is transferred; and a connection module provided between the transfer chamber and a front chamber of a processing apparatus configured to perform a predetermined process on the processing object, and configured to connect the transfer chamber and the front chamber, wherein the housing includes a rear member formed with a housing side opening through which the processing object is capable of passing, wherein the connection module includes: a first connection member arranged around the housing side opening when viewed from a depth direction in which the housing and the front chamber are arranged, and attached to the rear member; and a second connection member arranged around a front chamber side opening formed in the front chamber so as to allow the processing object to pass therethrough when viewed from the depth direction, and attached to the front chamber, wherein the first connection member includes a first cylindrical portion extending in the depth direction, and wherein the second connection member includes a second cylindrical portion extending in the depth direction, the second cylindrical portion being arranged to at least partially overlap with the first cylindrical portion in the depth direction and configured to be position-adjustable in the depth direction along the first cylindrical portion.

In the present disclosure, relative positions of the first connection member and the second connection member may be adjusted in the depth direction by merely moving the second cylindrical portion in the depth direction along the first cylindrical portion. In other words, the connection module may be expanded and contracted in the depth direction. Therefore, in the EFEM, a position of the connection module may be adjusted with a simple structure. In addition, in the present disclosure, since the second cylindrical portion is supported by the first cylindrical portion, it is possible to effectively suppress a load due to a weight of the second connection member from being applied to members constituting the front chamber.

According to a second aspect of the present disclosure, in the EFEM of the first aspect, the first connection member includes a flange portion attached to the rear member and configured to be position-adjustable with respect to the rear member in a direction in which the rear member extends.

In the present disclosure, with a simple structure, the position of the connection module may be adjusted even in the direction in which the rear member extends.

According to a third aspect of the present disclosure, in the EFEM of the first or second aspect, the rear member includes a first rear member whose position is fixed with respect to the housing, and includes a second rear member attached to the first rear member and to which the first connection member is attached, and the second rear member is configured to be position-adjustable with respect to the first rear member in a direction in which the first rear member extends.

In the present disclosure, by adjusting the position of the second rear member with respect to the first rear member, it is possible to absorb a design error of the rear member.

According to a fourth aspect of the present disclosure, in the EFEM of the first or second disclosure, at least one selected from the group of the first connection member and the second connection member is divided into four or more connectable connection pieces in a circumferential direction of the first cylindrical portion and the second cylindrical portion.

When both the first cylindrical portion and the second cylindrical portion are formed continuously over the entire circumference, it is necessary to insert one of the first cylindrical portion and the second cylindrical portion into the other in order to at least partially overlap the first cylindrical portion and the second cylindrical portion in the depth direction. Therefore, when a gap between an outer circumferential surface of one of the first cylindrical portion and the second cylindrical portion and an inner circumferential surface of the other is very narrow, it may take time and effort to perform the insertion. In the present disclosure, since at least one selected from the group of the first connection member and the second connection member is divided into four or more parts in the circumferential direction, the divided parts may be moved freely to some extent. As a result, the first cylindrical portion and the second cylindrical portion may be easily overlapped in advance in the depth direction.

According to a fifth aspect of the present disclosure, in the EFEM of the fourth aspect, the first cylindrical portion and the second cylindrical portion are in direct contact with each other.

In a configuration in which, for example, a packing is interposed between the first cylindrical portion and the second cylindrical portion, a high sealability may be ensured in the EFEM. Meanwhile, an EFEM whose housing is filled with, for example, an air may generally be operated without problems even in a case the sealability is somewhat low. In the present disclosure, by bringing the first cylindrical portion and the second cylindrical portion of the connection module into direct contact with each other, a certain degree of sealability may be ensured even without interposing a packing between the first cylindrical portion and the second cylindrical portion. Accordingly, cost of each member may be reduced in such an EFEM.

### BRIEF DESCRIPTION OF DRAWINGS

The accompanying drawings, which are incorporated in and constitute a part of the specification, illustrate embodiments of the present disclosure.

FIG. 1 is a schematic plan view of an EFEM according to the present embodiment and its surroundings.

FIG. 2 is a diagram showing an electrical configuration of the EFEM.

FIG. 3 is a front view of a housing.

FIG. 4 is a rear view of the housing.

FIG. 5 is an enlarged view of a part of FIG. 4.

FIG. 6A is a cross-sectional view taken along line VI(a)-VI(a) in FIG. 5, and FIG. 6B is an enlarged view of a part of FIG. 6A.

FIG. 7A is a perspective view of a connection module, and FIG. 7B is a front view of the connection module.

FIGS. 8A and 8B are front views of respective parts of the connection module, FIG. 8C is a cross-sectional view of a second connection member taken along line VIII(c)-VIII(c), and FIG. 8D is a cross-sectional view similar to FIG. 8C.

FIGS. 9A and 9B are explanatory diagrams showing a procedure of attaching the rear wall to the housing.

FIGS. 10A and 10B are explanatory diagrams showing a procedure of attaching the connection module to the rear wall.

FIGS. 11A and 11B are explanatory diagrams showing a method for adjusting a position of the second connection member.

FIGS. 12A and 12B are explanatory diagrams showing a procedure of attaching the connection module to the load lock chamber.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

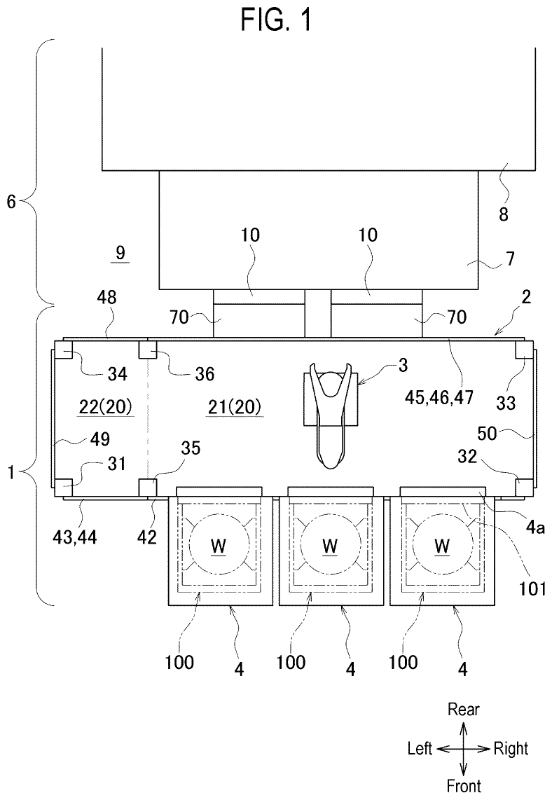

Next, embodiments of the present disclosure will be described. For the sake of convenience of description, directions shown in FIG. 1 are defined as front, rear, left and right directions. That is, a direction in which the EFEM (Equipment Front End Module) 1 and the processing apparatus 6 are arranged is defined as a front-rear direction (depth direction in the present disclosure). In the front-rear direction, an EFEM 1 side is defined as a front side (transfer chamber side). In the front-rear direction, a processing apparatus 6 side is defined as a rear side (front chamber side). A direction in which a plurality of load ports 4 are arranged and which is orthogonal to the front-rear direction is defined as a left-right direction. Further, a direction orthogonal to both the front-rear direction and the left-right direction is defined as an up-down direction.

### (Schematic Configuration of EFEM and Surroundings)

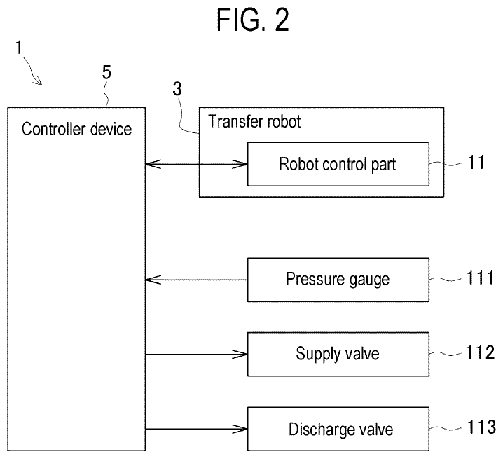

The schematic configuration of the EFEM 1 and its surroundings will be described with reference to FIGS. 1 and 2. FIG. 1 is a schematic plan view of the EFEM 1 and its surroundings according to the present embodiment. FIG. 2 is a diagram showing an electrical configuration of the EFEM 1. The EFEM 1 includes a housing 2, a transfer robot 3, a plurality of load ports 4, and a control device 5 (see FIG. 2). A processing apparatus 6 is arranged on the rear side of the EFEM 1. The processing apparatus 6 is an apparatus configured to perform a predetermined process on a wafer W (a processing object in the present disclosure) which is a semiconductor substrate. The predetermined process may be, for example, a process (sputtering, dry etching, etc.) performed in a vacuum chamber or may be other processes. The EFEM 1 transfers the wafer W between a FOUP (Front-Opening Unified Pod) 100 placed on the load port 4 and the processing apparatus 6 by using the transfer robot 3 arranged in the housing 2. The FOUP 100 is a container configured to be capable of accommodating a plurality of wafers W arranged vertically. A lid 101 is attached to the rear end of the FOUP 100 (an end on the housing 2 side in the front-rear direction). The FOUP 100 is transferred by, for example, a transfer device (not shown). The FOUP 100 is delivered between the transfer device and the load port 4.

The housing 2 is configured to connect the plurality of load ports 4 and the processing apparatus 6. As shown in FIG. 1, a transfer chamber 21 in which the wafer W is transferred is formed inside the housing 2. The transfer chamber 21 is substantially sealed with respect to a space outside the housing 2 (hereinafter, referred to as an external space 9). In the present embodiment, the transfer chamber 21 is filled with, for example, a clean air when the EFEM 1 is in operation. The housing 2 is configured such that an air circulates within an internal space 20 including the transfer chamber 21. The transfer chamber 21 is connected to a load lock chamber 7 (a front chamber in the present disclosure) of the processing apparatus 6 via a known gate valve 10 and a connection module 70 to be described later. The gate valve 10 is arranged, for example, on a rear side of the rear end of the housing 2. The gate valve 10 belongs to the load lock chamber 7. In the present embodiment, two gate valves 10 are arranged side by side in the left-right direction. The wafer W is transferred between the transfer chamber 21 and the load lock chamber 7 through one of the gate valves 10. The number of gate valves 10 is not limited thereto. A detailed description of the configuration of the gate valves 10 will be omitted.

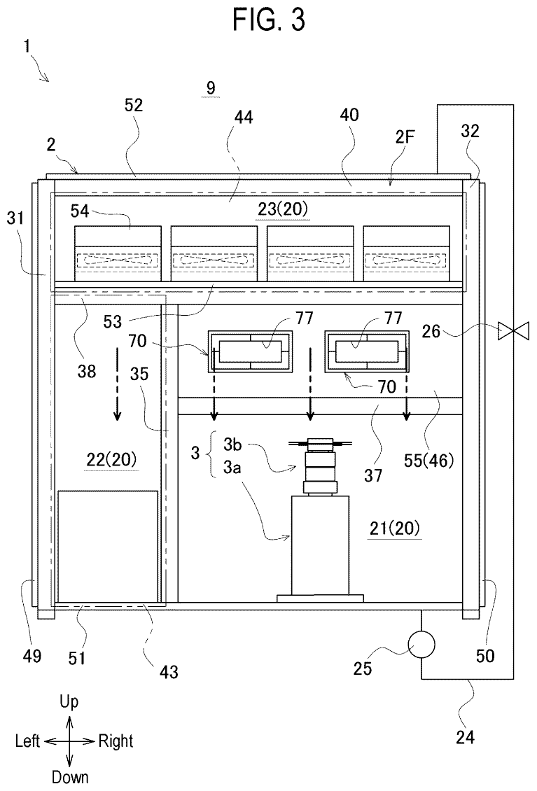

The transfer robot 3 is configured to transfer the wafer W within the transfer chamber 21. The transfer robot 3 includes, for example, a base part 3a (see FIG. 3), an arm mechanism 3b (see FIG. 3), and a robot control part 11 (see FIG. 2). The base part 3a is a part whose position within the transfer chamber 21 is fixed. The arm mechanism 3b is attached to the base part 3a and is configured to hold and transfer the wafer W. The transfer robot 3 mainly performs an operation of taking out a wafer W from the FOUP 100 and delivering the wafer W to the processing apparatus 6, and an operation of receiving the wafer W processed by the processing apparatus 6 and returning the wafer W to the FOUP 100.

Each of the plurality of load ports 4 (see FIG. 1) is configured such that the FOUP 100 is placed thereon. The plurality of load ports 4 are arranged side by side in the left-right direction. The rear ends of the respective load ports 4 are arranged along a front partition wall (a front wall 42 to be described later) of the housing 2. The load port 4 may be configured to be capable of replacing the gas in the FOUP 100 with another gas. A door 4a is provided at the rear end of the load port 4. The door 4a is opened and closed by a door opening/closing mechanism (not shown). The door 4a is configured to be capable of unlocking the lid 101 of the FOUP 100 and holding the lid 101. While the door 4a holds the unlocked lid 101, a door moving mechanism opens the door 4a, thereby opening the lid 101. This allows the wafer W in the FOUP 100 to be taken out by the transfer robot 3.

The control device 5 (see FIG. 2) is electrically connected to a robot control part 11 of the transfer robot 3, a control part (not shown) of the load port 4, and a control part (not shown) of the processing apparatus 6 and is configured to communicate with these control parts. The control device 5 is electrically connected to, for example, a measurement device such as a pressure gauge 111 or the like installed in the housing 2. The control device 5 is electrically connected to, for example, a supply valve 112 and a discharge valve 113. The supply valve 112 is provided, for example, in a supply pipe (not shown) configured to supply an air from the external space 9 into the housing 2, and is configured to be capable of opening and closing the supply pipe. The discharge valve 113 is provided, for example, in a discharge pipe (not shown) configured to discharge an air within the housing 2 to the external space 9, and is configured to be capable of opening and closing the discharge pipe. The control device 5 appropriately adjusts an atmosphere within the housing 2 (e.g., an atmospheric pressure in the internal space 20) by adjusting opening degrees of these valves. It is preferable that the atmospheric pressure in the internal space 20 is slightly higher than the atmospheric pressure in the external space 9 (i.e., slightly positive pressure).

The processing apparatus 6 (see FIG. 1) includes, for example, a load lock chamber 7 and a processing chamber 8. The load lock chamber 7 is a chamber configured to temporarily keep the wafer W on standby. The atmospheric pressure inside the load lock chamber 7 is maintained at, for example, an atmospheric pressure close to vacuum (an atmospheric pressure much lower than the atmospheric pressure in the transfer chamber 21). The load lock chamber 7 is connected to the transfer chamber 21 via a gate valve 10, for example. The processing chamber 8 is connected to the load lock chamber 7 via, for example, a door (not shown). In the processing chamber 8, a predetermined process is performed on the wafer W by a processing mechanism (not shown).

### (Configuration of Housing)

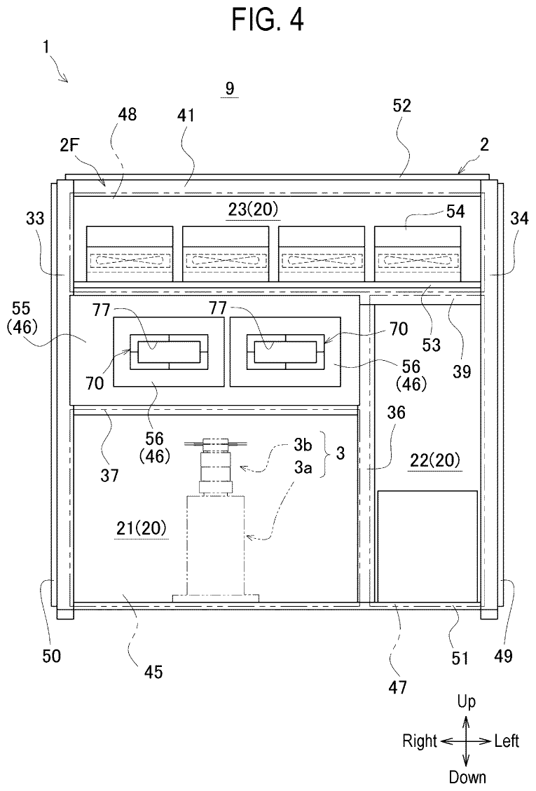

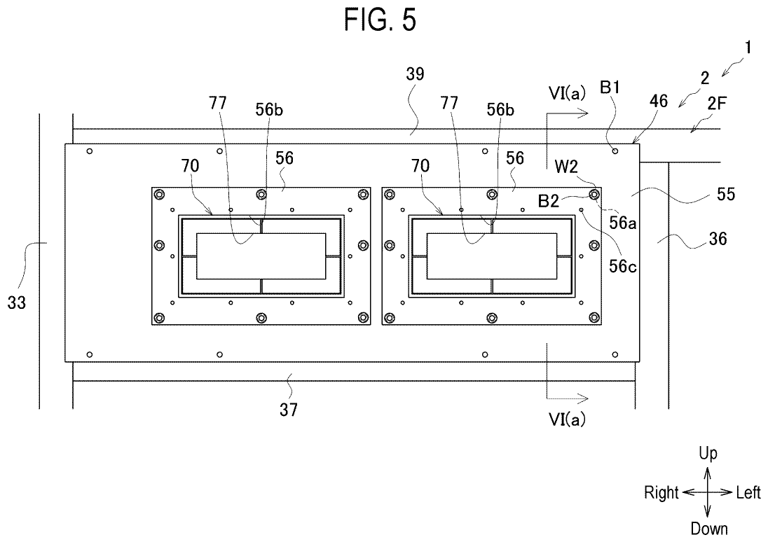

Next, a configuration of the housing 2 will be described with reference to FIGS. 1 and 3 to 5. FIG. 3 is a front view of the housing 2. FIG. 4 is a rear view of the housing 2. FIG. 5 is an enlarged view of a part of FIG. 4. In FIG. 3, some of the plurality of walls described later are omitted to avoid complication of the drawing. In FIGS. 3 and 4, some of the plurality of walls are shown with two-dot chain lines to avoid complication of the drawing. It should be noted that the left-right direction in FIG. 4 is opposite to the left-right direction in FIG. 3.

The housing 2 has a generally rectangular parallelepiped shape as a whole. As shown in FIGS. 1, 3 and 4, the housing 2 includes, for example, pillars 31 to 36, beams 37 to 41, front walls 42 to 44, rear walls 45 to 48, side walls 49 to 50, a bottom plate 51, a ceiling plate 52, and a support plate 53. The pillars 31 to 36 and the beams 37 to 41 are members configured to form an outer frame (frame 2F) of the housing 2. The internal space 20 of the housing 2 is generally sealed with respect to the external space 9 by the front walls 42 to 44, rear walls 45 to 48, side walls 49 to 50, bottom plate 51, and ceiling plate 52 attached to the frame 2F. The support plate 53 separates the transfer chamber 21 in the up-down direction from an upper space 23 (see FIGS. 3 and 4), which will be described later. These members are made of, for example, a general sheet metal (rolled metal plate having a thickness of 6 mm or less). Alternatively, at least some of these members may be made of a thick plate or the like having a thickness larger than 6 mm.

The pillars 31 to 36 are members arranged to extend in the up-down direction. As shown in FIG. 1, the pillar 31 is arranged at the left end and front end of the housing 2. The pillar 32 is arranged at the right end and front end of the housing 2. The pillar 33 is arranged at the right end and rear end of the housing 2. The pillar 34 is arranged at the left end and rear end of the housing 2. The pillars 31 to 34 extend over substantially the entire region of the housing 2 in the up-down direction (see FIGS. 3 and 4). As shown in FIG. 1, the pillar 35 is arranged between the pillars 31 and 32 in the left-right direction, and is also arranged at the front end of the housing 2. The pillar 36 is arranged between the pillars 33 and 34 in the left-right direction, and is also arranged at the rear end of the housing 2. The pillars 35 and 36 extend from the lower end to an upper intermediate portion of the housing 2 (see FIGS. 3 and 4).

The beams 37 to 40 are members arranged to extend in the horizontal direction. The beam 37 extends along the left-right direction and is fixed to the pillars 33 and 36 (see FIG. 4). The left end portion of the beam 37 is attached to an intermediate portion of the pillar 36 in the up-down direction. The right end portion of the beam 37 is attached to an intermediate portion of the pillar 33 in the up-down direction.

The beam 38 extends along the left-right direction and is fixed to the pillars 31, 32 and 35 (see FIG. 3). The left end portion of the beam 38 is attached to an intermediate portion of the pillar 31 in the up-down direction. The right end of the beam 38 is attached to an intermediate portion of the pillar 32 in the up-down direction. The intermediate portion of the beam 38 in the left-right direction is attached to the upper end portion of the pillar 35. The beam 39 extends along the left-right direction and is fixed to the pillars 33, 34 and 36 (see FIG. 4). The left end portion of the beam 39 is attached to an intermediate portion of the pillar 34 in the up-down direction. The right end portion of the beam 39 is attached to an intermediate portion of the pillar 33 in the up-down direction. The intermediate portion of the beam 39 in the left-right direction is attached to the upper end portion of the pillar 36.

The beam 40 extends along the left-right direction, and is fixed to the pillars 31 and 32 (see FIG. 3). The left end portion of the beam 40 is attached to the upper end portion of the pillar 31. The right end portion of the beam 40 is attached to the upper end portion of the pillar 32. The beam 41 extends along the left-right direction, and is fixed to the pillars 33 and 34 (see FIG. 4). The left end portion of the beam 41 is attached to the upper end portion of the pillar 34. The right end portion of the beam 41 is attached to the upper end portion of the pillar 33.

The front walls 42 to 44 are arranged at the front end portion of the housing 2. The front wall 42 (see FIG. 1) (not shown in FIG. 3) is a member configured to close an opening surrounded and defined by the pillars 32, 35, the beam 38, and the bottom plate 51. The front wall 42 is a member to which the load port is fixed. The front wall 43 (see FIGS. 1 and 3) is a member configured to close an opening surrounded and defined by the pillars 31 and 35, the beam 38, and the bottom plate 51. The front wall 44 (see FIGS. 1 and 3) is a member configured to close an opening surrounded and defined by the pillars 31 and 32 and the beams 38 and 40.

The rear walls 45 to 48 are arranged at the rear end portion of the housing 2. The rear wall 45 (see FIGS. 1 and 4) is a member configured to close an opening surrounded and defined by the pillars 33 and 36, the beam 37, and the bottom plate 51. A rear wall 46 (see FIGS. 1, 4, and 5) (the rear member in the present disclosure) is a member configured to close an opening surrounded and defined by the pillars 33 and 36 and the beams 37 and 39. The rear wall 46 extends in the up-down direction and the horizontal direction. More details of the rear wall 46 will be described later. The rear wall 47 (see FIGS. 1 and 4) is a member configured to close an opening surrounded and defined by the pillars 34 and 36, the beam 39, and the bottom plate 51. The rear wall 48 (see FIGS. 1 and 4) is a member configured to close an opening surrounded and defined by the pillars 33 and 34 and the beams 39 and 41.

The side wall 49 is arranged at the left end portion of the housing 2. The side wall 50 is arranged at the right end portion of the housing 2. The bottom plate 51 is arranged at the bottom of the housing 2 (see FIGS. 3 and 4). The ceiling plate 52 is arranged on a ceiling of the housing 2 (see FIGS. 3 and 4). The support plate 53 extends in the horizontal direction. The support plate 53 is provided, for example, on portions of the beams 38 and 39 arranged between the pillars 32 and 35 in the left-right direction.

The internal space 20 of the housing 2 formed as described above includes, for example, a transfer chamber 21, an equipment installation chamber 22, and an upper space 23. The transfer chamber 21 is a space in which the transfer robot 3 transfers the wafer W as described above. The equipment installation chamber 22 is arranged adjacent to a lateral side of the transfer chamber 21, for example, and is connected to the transfer chamber 21. In the equipment installation chamber 22, equipment (not shown) such as a known aligner and/or wafer reversing device is installed. The upper space 23 is arranged above the transfer chamber 21 and the equipment installation chamber 22, for example. The upper space 23 is separated from the transfer chamber 21 and the equipment installation chamber 22 by a support plate 53. An opening (not shown) connecting the transfer chamber 21 and the equipment installation chamber 22 to the upper space 23 is formed at a central portion in the front-rear direction of the support plate 53 arranged in the upper space 23. In the upper space 23, for example, a plurality of known fan filter units 54 are arranged side by side in the left-right direction. The plurality of fan filter units 54 are installed, for example, on the support plate 53. Each fan filter unit 54 is configured to clean the air in the upper space 23 and send the same to the transfer chamber 21 and the equipment installation chamber 22. An air is supplied to the upper space 23 through, for example, the above-described supply pipe (not shown).

The air cleaned by the fan filter unit 54 is sent downward from the upper space 23. The air forms a laminar flow in the transfer chamber 21 and the equipment installation chamber 22, and flows downward (see the two-dot chain line arrow in FIG. 3). The air that has reached the lower end portions of the transfer chamber 21 and the equipment installation chamber 22 is discharged through, for example, the above-mentioned discharge pipe (not shown).

The EFEM 1 may be configured to be capable of circulating a part of the air within the internal space 20. More specifically, for example, a circulation duct 24 (see FIG. 3) configured to return the air in the transfer chamber 21 and the equipment installation chamber 22 to the upper space 23 may be provided. A part of the air that has reached the lower end portions of the transfer chamber 21 and the equipment installation chamber 22 may rise through the circulation duct 24 and return to the upper space 23. A fan 25 may be provided at an intermediate portion of the circulation duct 24 to forcefully send the air in the transfer chamber 21 and the equipment installation chamber 22 to the upper space 23. A valve 26 configured to open and close the circulation duct 24 may be provided at the intermediate portion of the circulation duct 24. When the valve 26 is opened, a part of the air in internal space 20 circulates. When the valve 26 is closed, the air in internal space 20 does not circulate. In the present embodiment, the circulation duct 24 may not be provided. That is, the air in the internal space 20 may be supplied exclusively through the above-mentioned supply pipe and may be discharged through the discharge pipe.

Furthermore, the EFEM 1 includes two connection modules 70 (see FIGS. 1, 3, and 4). The connection modules 70 are configured to connect the transfer chamber 21 and the load-lock chamber 7 while ensuring a sealability of the transfer chamber 21 and the load-lock chamber 7 to some extent. The two connection modules 70 are attached to the rear wall 46.

### (Front End of Load Lock Chamber)

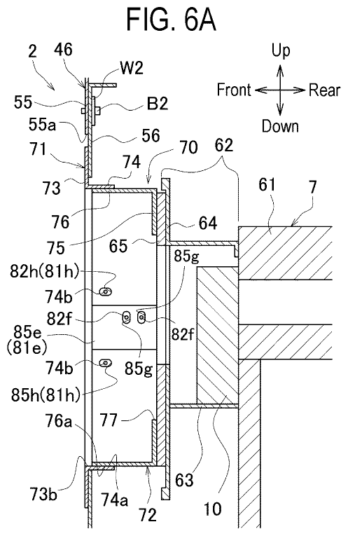

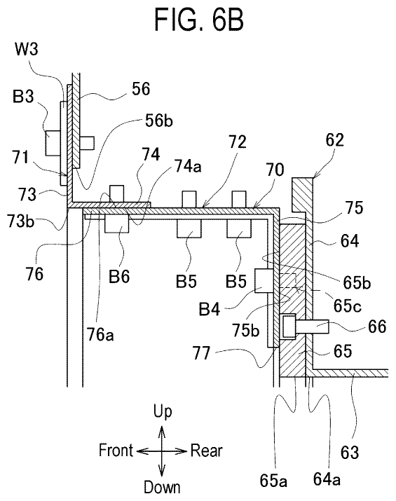

Next, the front end portion of the load lock chamber 7 will be described with reference to FIGS. 6A and 6B. FIG. 6A is a cross-sectional view taken along line VI(a)-VI(a) in FIG. 5. FIG. 6B is an enlarged view of a part of FIG. 6A.

As shown in FIG. 6A, the front end portion of the load lock chamber 7 is formed by, for example, a frame member 61. For example, a flange member 62 is attached to the front end of the frame member 61. The flange member 62 is configured to allow the wafer W to pass through its interior space in the front-rear direction. The flange member 62 has a cylindrical portion 63 formed in a cylindrical shape and a flange portion 64 formed substantially in a flat-plate shape. The cylindrical portion 63 extends in the front-rear direction. The cylindrical portion 63 is fixed to the frame member 61. The gate valve 10 is accommodated in a space inside the cylindrical portion 63. The space inside the cylindrical portion 63 is connected to the load lock chamber 7 via the gate valve 10. The flange portion 64 is formed at the front end portion of the cylindrical portion 63. As shown in FIG. 6B, the flange portion 64 is formed with an opening 64a passing therethrough in the front-rear direction. The opening 64a has a size that allows the wafer W to pass therethrough in the front-rear direction. For example, a frame-shaped intervening member 65 is fixed to the front end of the flange portion 64 by bolts 66. The intervening member 65 is formed with an opening 65a (an opening on the front chamber side in the present disclosure) passing therethrough in the front-rear direction. The opening 65a has a size that allows the wafer W to pass therethrough in the front-rear direction. The intervening member 65 is a member configured to connect the flange portion 64 and the rear end portion of the connection module 70. That is, the rear end portion of the connection module 70 is fixed to the intervening member 65. More specifically, a front end surface 65b that contacts a rear end surface 75b of a second connection member 72, which will be described later, is formed at the front end of the intervening member 65. A screw hole 65c with which a bolt B4, which will be described later, is screw-coupled is formed in the front end surface 65b.

When installing the EFEM 1, there is a need for means for easily positioning the connection module 70 with respect to the load lock chamber 7. This is because an enormous amount of effort would be required when the position of the entire housing 2 is adjusted to absorb design errors of the housing 2 and the load lock chamber 7. Although studies on such a configuration have been conducted from the past, further improvement in handling characteristics, weight reduction of members, and the like are required. Therefore, in the EFEM 1 of the present embodiment, the housing 2 and the connection module 70 have the following configurations to enable adjustment of the position of the connection module 70 with a simple structure.

### (More Detailed Configuration of Housing and Connection Module)

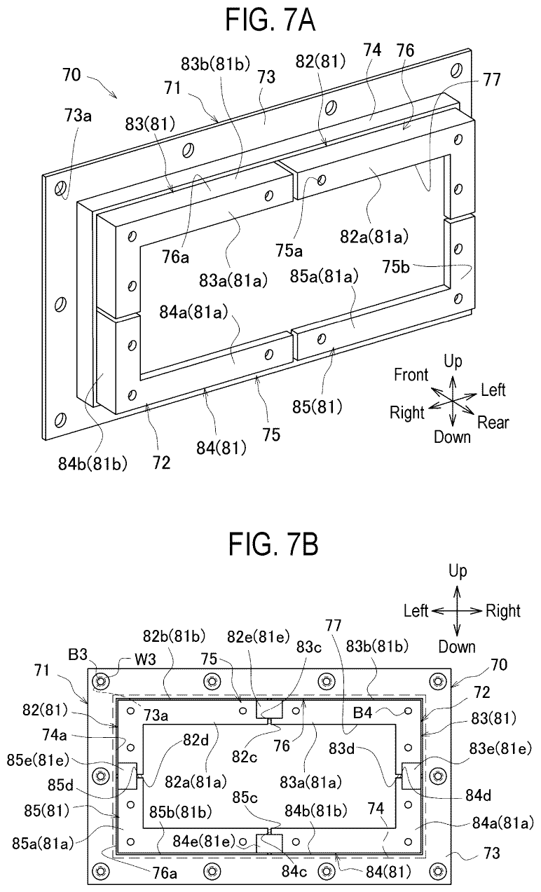

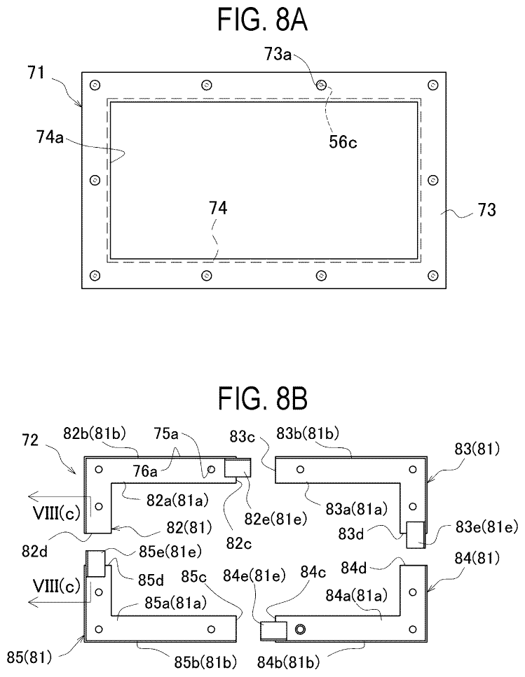

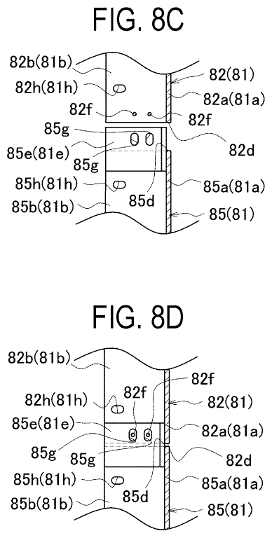

More detailed configurations of the housing 2 and the connection module 70 will be described with reference to FIGS. 5 to 8D. FIG. 7A is a perspective view of the connection module 70. FIG. 7B is a front view of the connection module 70. FIG. 8A is a front view of a first connection member 71, which will be described later. FIG. 8B is a front view of a second connection member 72, which will be described later. In FIG. 8B, the second connection member 72 is divided into four parts. FIG. 8C is a cross-sectional view of the second connection member taken along line VIII (c)-VIII (c). FIG. 8D is a sectional view similar to FIG. 8C.

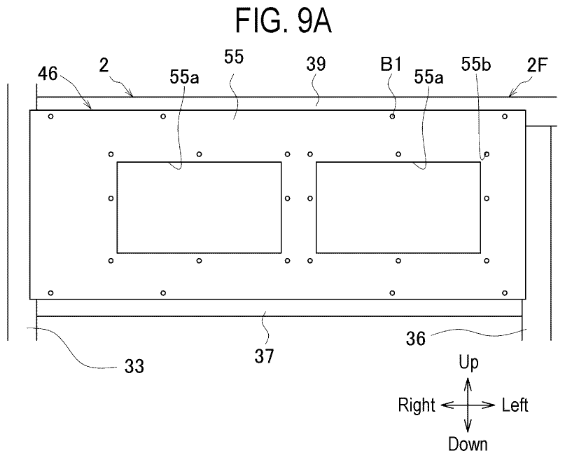

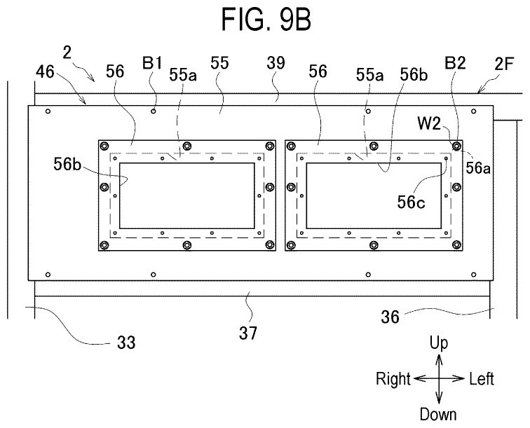

First, a more detailed configuration of the housing 2 will be described. As shown in FIG. 5, the rear wall 46 of the housing 2 includes, for example, a first rear member 55 and two second rear members 56. The first rear member 55 is, for example, a substantially rectangular plate member. The first rear member 55 is fixed to the pillars 33 and 36 and the beams 37 and 39 from the outside of the housing 2 by, for example, a plurality of (eight in the present embodiment) bolts B1. A position of the first rear member 55 with respect to the housing 2 (more precisely, a position of the frame 2F) is fixed. The first rear member 55 has two openings 55a each passing therethrough in the front-rear direction (see FIGS. 6A and 9A). A plurality of screw holes 55b (see FIG. 9A) with which bolts B2 to be described later are respectively screw-coupled are formed around each opening 55a.

Each of the two second rear members 56 is, for example, a substantially rectangular plate member. As shown in FIG. 5, each second rear member 56 is attached to the first rear member 55 from the outside of the housing 2 by a plurality of bolts B2. More specifically, the second rear member 56 has such a size that it may close the opening 55a of the first rear member 55. A plurality of insertion holes 56a (see FIG. 5) through which the bolts B2 are inserted are formed near an outer edge of the second rear member 56. Each insertion hole 56a has an inner diameter (e.g., 14 mm) larger than an outer diameter (e.g., 4 mm) of a screw portion of the bolt B2. Thus, it is possible to adjust the positions of the second rear member 56 with respect to the first rear member 55 in the up-down direction and the left-right direction. For example, a washer W2 is interposed between the second rear member 56 and the head of each bolt B2 in the front-rear direction. The outer diameter of the washer W2 is, for example, larger than the inner diameter of the insertion hole 56a. The second rear member 56 is formed with a substantially rectangular opening 56b (see FIGS. 5 and 9B) (a housing side opening in the present disclosure) passing therethrough in the front-rear direction. The opening 56b is a hole through which a first cylindrical portion 74 of the first connection member 71 to be described later passes from the inside toward the outside of the housing 2. The opening 56b is smaller than the opening 55a of the first rear member 55. A plurality of screw holes 56c (see FIG. 5) with which bolts B3 to be described later are respectively screw-coupled are formed in the vicinity of the opening 56b.

Next, a more detailed configuration of the connection module 70 will be described. As shown in FIGS. 6A to 8D, the connection module 70 includes a first connection member 71 and a second connection member 72. The first connection member 71 is attached to, for example, the second rear member 56. The second connection member 72 is attached to, for example, the intervening member 65. The first connection member 71 and the second connection member 72 are in contact with each other. The second connection member 72 is configured to be position-adjustable with respect to the first connection member 71 in the front-rear direction.

The first connection member 71 is a substantially rectangular member when viewed from the front-rear direction (see FIGS. 7A to 8A). The first connection member 71 is made of, for example, a sheet metal or a thick plate. The first connection member 71 is screw-fixed to a portion of the second rear member 56 near the opening 56b by, for example, a plurality of bolts B3 (see FIGS. 6B and 7B). Each bolt B3 is screw-coupled with a screw hole 56c (see FIGS. 5 and 8A). As shown in FIGS. 6A to 8A, the first connection member 71 includes a first flange portion 73 (flange portion in the present disclosure) having a substantially rectangular frame shape and a first cylindrical portion 74 having a substantially rectangular parallelepiped cylindrical shape.

As shown in FIG. 7A, the first flange portion 73 is provided at the rear end portion of the first connection member 71. The first flange portion 73 has a plurality of insertion holes 73a through which the screwed portions of the plurality of bolts B3 are respectively inserted. Each insertion hole 73a has an inner diameter (e.g., 14 mm) larger than the outer diameter (e.g., 4 mm) of the screwed portion of the bolt B3. Thus, it is possible to adjust the positions of the first flange portion 73 with respect to the second rear member 56 in the up-down direction and the left-right direction. For example, a washer W3 (see FIG. 6B) is interposed between the first flange portion 73 and the head of each bolt B3 in the front-rear direction. The outer diameter of the washer W3 is, for example, larger than the inner diameter of the insertion hole 73a. The first flange portion 73 has a substantially rectangular opening 73b passing therethrough in the front-rear direction. The first cylindrical portion 74 protrudes rearward from the vicinity of the opening 73b (i.e., from the vicinity of the inner edge of the first flange portion 73).

The first cylindrical portion 74 is a substantially rectangular cylindrical portion. The first cylindrical portion 74 extends rearward from the vicinity of the inner edge of the first flange portion 73. The first cylindrical portion 74 has an inner circumferential surface 74a (the circumferential surface in the present disclosure) (see FIGS. 6A, 6B, and 8A). When viewed from the front-rear direction, a size of the inner circumferential surface 74a is substantially the same as a size of the opening 73b. The second connection member 72 is in contact with the inner circumferential surface 74a, as will be described later. A plurality of screw holes 74b (see FIG. 6A) extending in a thickness direction of the first cylindrical portion 74 are formed in the inner circumferential surface 74a.

The second connection member 72 is a substantially rectangular member when viewed from the front-rear direction (see FIGS. 7A and 7B). The second connection member 72 is made of, for example, a sheet metal or a thick plate. The second connection member 72 is screw-fixed to the intervening member 65 by, for example, a plurality of bolts B4 (see FIGS. 6B and 7B). The plurality of bolts B4 are screw-coupled with a plurality of screw holes 65c formed in the intervening member 65. As shown in FIGS. 6A to 7B, the second connection member 72 includes a second flange portion 75 having a substantially rectangular frame shape and a second cylindrical portion 76 having a substantially rectangular parallelepiped cylindrical shape.

The second flange portion 75 is provided at the front end portion of the second connection member 72. The second flange portion 75 has a plurality of insertion holes 75a (see FIG. 7A) through which the screwed portions of the plurality of bolts B4 (see FIG. 7B) are respectively inserted. Each insertion hole 75a has, for example, an inner diameter slightly larger than the outer diameter (e.g., 4 mm) of the screw portion of the bolt B4. A rear end surface 75b that contacts the front end surface 65b of the intervening member 65 is formed at the rear end of the second flange portion 75 (see FIG. 6B). The second flange portion 75 has a substantially rectangular opening 77 passing therethrough in the front-rear direction.

The second cylindrical portion 76 is a substantially rectangular parallelepiped cylindrical portion. The second cylindrical portion 76 extends forward from the vicinity of the outer edge of the second flange portion 75. The second cylindrical portion 76 is formed with an outer circumferential surface 76a (see FIGS. 6A and 6B). The outer circumferential surface 76a is in direct contact with the inner circumferential surface 74a of the first cylindrical portion 74 of the first connection member 71 over substantially the entire circumference. The second cylindrical portion 76 is arranged to partially overlap with the first cylindrical portion 74 in the front-rear direction (see FIGS. 6A and 6B).

For the sake of convenience of description, a direction in which the first cylindrical portion 74 and the second cylindrical portion 76 extend over substantially the entire circumference when viewed from the front-rear direction is referred to as a circumferential direction (illustration of which is omitted). The second connection member 72 is divided into four connectable parts in the circumferential direction of the first cylindrical portion 74 and the second cylindrical portion 76 (see FIGS. 7A and 8B). For the sake of convenience of description, these four parts will be referred to as four connection pieces 81 (connection pieces 82, 83, 84, and 85). For example, the connection piece 81 located on the upper left side is the connection piece 82. The connection piece 81 located on the upper right side is the connection piece 83. The connection piece 81 located on the lower right side is the connection piece 84. The connection piece 81 located on the lower left side is the connection piece 85.

Each of the four connection pieces 81 is, for example, a component having a substantially L-like shape when viewed from the front-rear direction (see FIGS. 7B and 8B). Each of the four connection pieces 81 includes a flange piece 81a that constitutes the second flange portion 75 and a cylindrical piece 81b that constitutes the second cylindrical portion 76. That is, the connection pieces 82, 83, 84, and 85 have flange pieces 82a, 83a, 84a, and 85a, and cylinder pieces 82b, 83b, 84b, and 85b respectively. Each of the four connection pieces 81 is connected to two other connection pieces 81 adjacent to each other in the circumferential direction (see FIG. 7B). Thus, the second flange portion 75 is formed by four flange pieces 81a. Further, the second cylindrical portion 76 is formed by four cylindrical pieces 81b.

As shown in FIG. 7B, a right end surface 82c is formed at the right ends of the flange piece 82a and the cylinder piece 82b. A lower end surface 82d is formed at the lower ends of the flange piece 82a and the cylinder piece 82b. A left end surface 83c is formed at the left ends of the flange piece 83a and the cylinder piece 83b. A lower end surface 83d is formed at the lower ends of the flange piece 83a and the cylinder piece 83b. A left end surface 84c is formed at the left ends of the flange piece 84a and the cylinder piece 84b. An upper end surface 84d is formed at the upper ends of the flange piece 84a and the cylinder piece 84b. A right end surface 85c is formed at the left ends of the flange piece 85a and the cylinder piece 85b. An upper end surface 85d is formed at the upper ends of the flange piece 85a and the cylinder piece 85b. The right end surface 82c and the left end surface 83c face each other. The lower end surface 83d and the upper end surface 84d face each other. The left end surface 84c and the right end surface 85c face each other. The upper end surface 85d and the lower end surface 82d face each other.

When the outer circumferential surface 76a of the second cylindrical portion 76 is in contact with the inner circumferential surface 74a of the first cylindrical portion 74 over substantially the entire circumference, a slight gap is formed between the right end surface 82c and the left end surface 83c. Similarly, slight gaps are formed between the lower end surface 83d and the upper end surface 84d, between the left end surface 84c and the right end surface 85c, and between the upper end surface 85d and the lower end surface 82d.

Each of the four connection pieces 81 has a connection portion 81e to be connected to another connection piece 81. In other words, the connection pieces 82, 83, 84, and 85 have connection portions 82e, 83c, 84c, and 85e, respectively (see FIG. 7B and FIG. 8B). The connection portion 81e is, for example, a substantially plate-shaped portion. For example, the connection portion 82e extends from the right end portions of the flange piece 82a and the cylinder piece 82b, and is provided to protrude to the right beyond the right end surface 82c. The connection portion 82e is arranged to partially overlap with the connection piece 83 in the left-right direction. The connection portion 83e extends from the lower ends of the flange piece 83a and the cylinder piece 83b, and is provided to protrude downward beyond the lower end surface 83d. The connection portion 83e is arranged to partially overlap with the connection piece 84 in the up-down direction. The connection portion 84e extends from the left end portions of the flange piece 84a and the cylinder piece 84b, and is provided to protrude to the left beyond the left end surface 84c. The connection portion 84e is arranged to partially overlap with the connection piece 85 in the left-right direction. A connection portion 85e extends from the upper end portions of the flange piece 85a and the cylinder piece 85b, and is provided to protrude upward beyond the upper end surface 85d. The connection portion 85e is arranged to partially overlap with the connection piece 82 in the up-down direction. Each of the four connection portions 81e extends, for example, along the flange piece 81a and the cylinder piece 81b (see FIGS. 8B to 8D).

A configuration of connecting one connection piece 81 to another connection piece 81 will be described with reference to FIGS. 8C and 8D. In FIGS. 8C and 8D, a portion that connects the connection piece 82 and the connection piece 85 is illustrated. For example, the cylinder piece 82b of the connection piece 82 is formed with two screw holes 82f extending in a thickness direction of the cylinder piece 82b. The connection portion 85e of the connection piece 85 is formed with two position adjustment holes 85g passing therethrough in substantially the same direction as a direction in which the screw holes 82f extends (hereinafter referred to as an extension direction). Each position adjustment hole 85g is formed to extend in a direction (up-down direction) in which the connection piece 82 and the connection piece 85 are adjacent to each other. The two screw holes 82f are arranged at positions where, when the connection piece 82 and the connection piece 85 are connected, the two screw holes 82f may fit within the two position adjustment holes 85g respectively as viewed from the extension direction (see FIG. 8D). Since other portions of each connection piece 81 also have the same configuration (except for the direction), description thereof will be omitted.

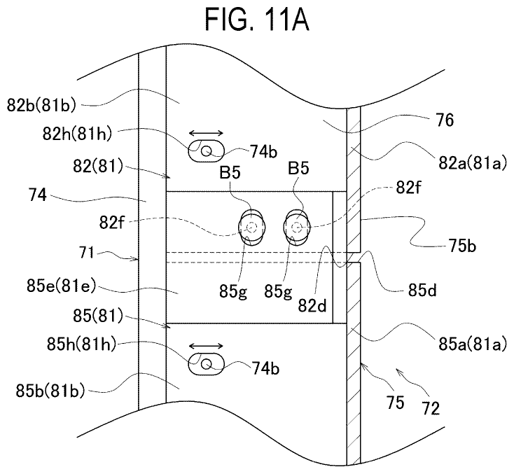

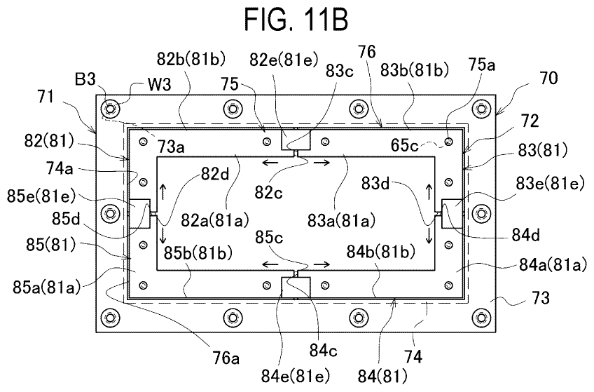

The connection piece 82 and the connection piece 85 are connected, for example, by bolts B5 (see FIG. 11A) screw-coupled with the respective screw holes 82f, as described later. More specifically, the connection piece 85 is fixed to the connection piece 82 by sandwiching the connection portion 85e between the cylinder piece 82b and the head of the bolt B5. The number of screw holes 82f and the number of position adjustment holes 85g are not limited thereto. Since other portions of each connection piece 81 also have the same configuration (except for the direction), the explanation thereof will be omitted.

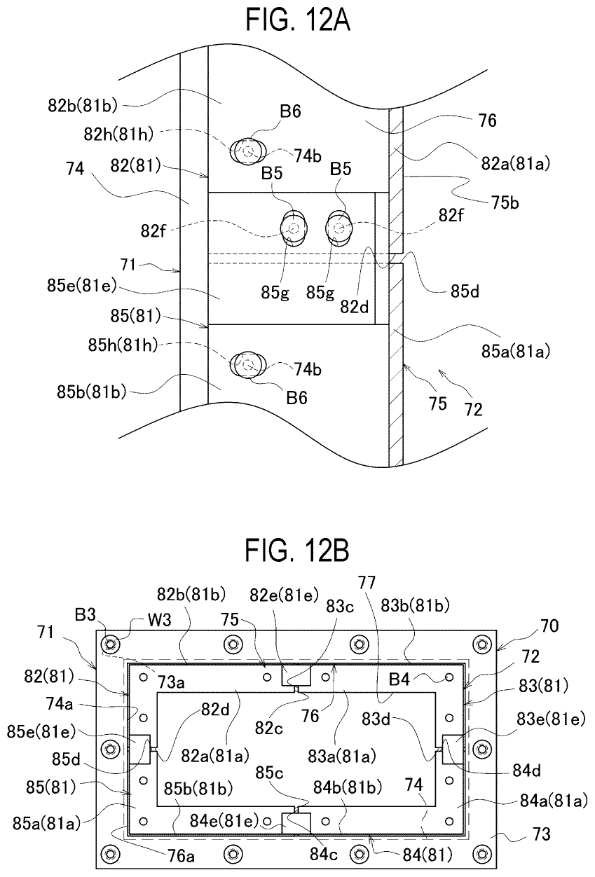

Furthermore, the connection module 70 is configured to be capable of being expanded and contracted in the front-rear direction (so-called telescopic structure). That is, the connection module 70 is configured such that the position of the second cylindrical portion 76 with respect to the first cylindrical portion 74 may be adjusted in the front-rear direction. For example, as shown in FIGS. 8C and 8D, the cylinder piece 81b of the connection piece 81 is formed with a plurality of position adjustment holes 81h passing therethrough in a thickness direction of the cylinder piece 81b and extending in the front-rear direction (see position adjustment holes 82h and 85h). Each of the plurality of screw holes 74b (see FIG. 6A) described above is arranged so as to fit within one of the plurality of position adjustment holes 81h when viewed from the thickness direction. A bolt B6 (see FIG. 12A) inserted into the corresponding position adjustment hole 81h is screw-coupled with each screw hole 74b.

### (Installation Method of EFEM)

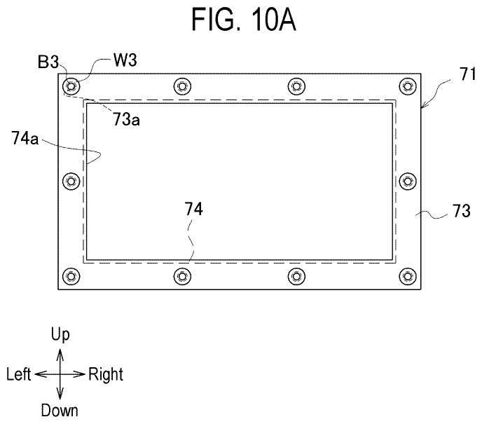

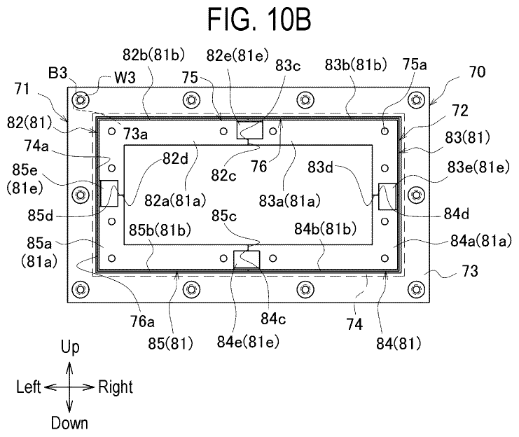

Next, a method of installing the EFEM 1 having the above-described configuration will be described with reference to FIGS. 9A to 12B. FIGS. 9A and 9B are explanatory diagrams showing a procedure of attaching the rear wall 46 to the housing 2. FIGS. 10A and 10B are explanatory diagrams showing a procedure for attaching the connection module 70 to the rear wall 46. FIGS. 11A and 11B are explanatory diagrams showing a method of adjusting the position of the second connection member 72. FIGS. 12A and 12B are explanatory diagrams showing a procedure of attaching the connection module 70 to the load lock chamber 7. Directions in FIGS. 11A and 12A are, for example, the same as the directions in FIG. 6A. Directions in FIG. 11B and FIG. 12B are, for example, the same as the directions in FIG. 7B.

First, the EFEM 1 is divided into a plurality of components and transported to a factory where the processing apparatus 6 is installed (or has already been installed). The plurality of components includes the rear wall 46. The rear wall 46 is shipped with the two second rear members 56 pre-aligned with the first rear member 55. More specifically, first, the first rear member 55 is screw-fixed to the pillars 33 and 36 and the beams 37 and 39 (see FIG. 9A). Next, the two second rear members 56 are aligned with the first rear member 55 and then screw-fixed to the first rear member 55 (see FIG. 9B).

Thereafter, the processing apparatus 6 and the housing 2 are installed, for example, in a predetermined clean room in a factory. After the processing apparatus 6 is installed, the housing 2 is aligned with the processing apparatus 6. Due to a design error of the housing 2 and a design error of the processing apparatus 6, a slight positional deviation may occur between the second rear member 56 and the intervening member 65 (see FIG. 6A).

A worker enters the internal space 20 of the housing 2 (more specifically, the transfer chamber 21) and attaches the connection module 70 to the housing 2 and the load lock chamber 7. That is, in the present embodiment, there is no need to perform the attachment work of the connection module 70 in the external space 9.

First, the worker screw-fixes the first connection member 71 to the second rear member 56 by using the plurality of bolts B3 (see FIG. 10A). At this time, the worker temporarily fixes the first connection member 71 with the plurality of bolts B3, and loosely fits the screwed portions of the plurality of bolts B3 into the plurality of insertion holes 73a, respectively. In this state, the worker adjusts the position of the first connection member 71 in the up-down direction and the left-right direction. Thereafter, the worker fully tightens the plurality of bolts B3. As a result, a misalignment between the first connection member 71 and the intervening member 65 (see FIG. 6A) may be substantially eliminated in the up-down direction and the left-right direction. That is, it is possible to absorb the design error of the housing 2 and the design error of the processing apparatus 6.

Next, the worker temporarily assembles the second connection member 72 by connecting the plurality of connection pieces 82 to 85 to each other. More specifically, the worker overlaps the connection portion 81e of each connection piece 81 with another corresponding connection piece 81 in the up-down direction or the left-right direction (see, e.g., FIG. 8D, FIG. 10B, and the like). The worker temporarily fixes each connection portion 81e to another connection piece 81 by using a plurality of bolts B5 (see FIG. 11A). In this state, the worker brings the right end surface 82c and the left end surface 83c close to each other enough to come into contact with each other (see FIG. 10B). Similarly, the worker brings the lower end surface 83d and the upper end surface 84d, the left end surface 84c and the right end surface 85c, and the upper end surface 85d and the lower end surface 82d close to one another enough to come into contact with one another. As a result, when the second connection member 72 is temporarily assembled, the outer circumferential surface 76a of the second cylindrical portion 76 is slightly smaller than when it is in contact with the inner circumferential surface 74a of the first cylindrical portion 74. Therefore, the second connection member 72 may be easily inserted into an internal space of the first cylindrical portion 74 in the front-rear direction.

Next, the worker inserts the second connection member 72 into the internal space of the first cylindrical portion 74 from the rear side of the first connection member 71 (see FIGS. 10B and 11A). For example, the worker moves the second connection member 72 rearward until the rear end surface 75b (see FIG. 6B) of the second flange portion 75 contacts the front end surface 65b (see FIG. 6B) of the intervening member 65. At this time, as shown in FIG. 11A, the second cylindrical portion 76 may be moved in the front-rear direction in a range in which the screw hole 74b of the second connection member 72 fits within the position adjustment hole 81h when viewed from the thickness direction of the first cylindrical portion 74. In this way, the position of the second cylindrical portion 76 may be adjusted in the front-rear direction along the first cylindrical portion 74. Thereafter, the worker may temporarily tighten the plurality of bolts B4 and B6 into the predetermined screw holes respectively.

Next, the worker moves the cylinder piece 81b of each connection piece 81 outward when viewed from the front-rear direction such that the outer circumferential surface 76a of the second cylindrical portion 76 comes into contact with the inner circumferential surface 74a of the first cylindrical portion 74 (see FIG. 11B). Next, the worker fully tightens the plurality of bolts B5 (see FIG. 11A) to complete the assembly of the second cylindrical portion 76. Further, the worker fixes the second cylindrical portion 76 to the first cylindrical portion 74 with the plurality of bolts B6 (see FIG. 12A). Further, the worker fixes the second flange portion 75 to the load lock chamber 7 (more specifically, the intervening member 65) with the plurality of bolts B4 (see FIG. 12B). In the manner described above, the assembly of the connection module 70 and the attachment of the connection module 70 to the housing 2 and the load lock chamber 7 are completed.

The connection module 70 mainly includes the first connection member 71 and the second connection member 72. The first connection member 71 is supported by the second rear member 56. Further, the second connection member 72 is supported by the first connection member 71. Therefore, a load on the load lock chamber 7 due to a weight of the connection module 70 is small.

As described above, a relative position between the first connection member 71 and the second connection member 72 may be adjusted in the front-rear direction by merely moving the second cylindrical portion 76 in the front-rear direction along the first cylindrical portion 74. In other words, the connection module 70 may be expanded and contracted in the front-rear direction. Therefore, in the EFEM 1, the position of the connection module 70 may be adjusted with a simple structure. Since the second cylindrical portion 76 is supported by the first cylindrical portion 74, the load due to the weight of the second connection member 72 is effectively suppressed from being applied to the members constituting the load lock chamber 7.

Further, the first connection member 71 has the first flange portion 73 whose position may be adjusted with respect to the second rear member 56 of the rear wall 46. Thus, the position of the connection module 70 may be adjusted with a simple structure even in a direction in which the rear wall 46 extends.

Moreover, the position of the second rear member 56 may be adjusted with respect to the first rear member 55 in the up-down direction and the left-right direction (i.e., a direction in which the first rear member 55 extends). Therefore, by adjusting the position of the second rear member 56 with respect to the first rear member 55, it is possible to absorb the design error of the rear wall 46.

Furthermore, since the second connection member 72 is divided into four parts in the circumferential direction, the divided parts may be moved freely to some extent. Thus, the first cylindrical portion 74 and the second cylindrical portion 76 may be easily overlapped in advance in the front-rear direction.

Further, by bringing the first cylindrical portion 74 and the second cylindrical portion 76 of the connection module 70 into direct contact with each other, a certain degree of sealability may be ensured without sandwiching a packing (not shown) between the first cylindrical portion 74 and the second cylindrical portion 76. Therefore, cost of each member may be reduced in the EFEM 1 filled with the ambient air.

Next, modifications of the above-described embodiment will be described. The components having the same configurations as those of the above-described embodiment will be designated by like reference numerals, and the description thereof will be omitted as appropriate.

(1) In the above-described embodiment, the second connection member 72 is attached to the first connection member 71 after the first connection member 71 is attached to the second rear member 56. However, the present disclosure is not limited thereto. For example, the connection module 70 may be attached to the second rear member 56 by using the following procedure. The worker first temporarily fixes the plurality of connection pieces 81 of the second connection member 72 to one another with the plurality of bolts B5, and temporarily fixes the second connection member 72 to the first connection member 71 with the plurality of bolts B6. In this way, the connection module 70 may be loosely assembled in advance in a state in which the position of the second connection member 72 with respect to the first connection member 71 may be finely adjusted. Thereafter, the worker temporarily fixes the entire connection module 70 to the second rear member 56 and adjusts the positions of the first connection member 71 and the second connection member 72. Finally, the worker fully tightens each bolt that has been temporarily tightened. The installation work of the connection module 70 may be completed in the manner described above.

(2) In the above-described embodiment, the second connection member 72 is divided into four parts in the circumferential direction. However, the present disclosure is not limited thereto. The second connection member 72 may be divided into five or more parts in the circumferential direction.

(3) In the above-described embodiment, the second rear member 56 is position-adjustable with respect to the first rear member 55 in the up-down direction and the left-right direction. However, the present disclosure is not limited thereto. For example, the entire rear wall 46 may be position-adjustable with respect to the frame 2F. Alternatively, the rear wall 46 may not be configured to be position-adjustable with respect to the frame 2F.

(4) In the above-described embodiment, the first flange portion 73 is position-adjustable with respect to the rear wall 46 in the up-down direction and the left-right direction. However, the present disclosure is not limited thereto. For example, the first flange portion 73 may not be configured to be position-adjustable with respect to the rear wall 46.

(5) In the above-described embodiment, the inner circumferential surface 74a of the first cylindrical portion 74 and the outer circumferential surface 76a of the second cylindrical portion 76 are in contact with each other. However, the present disclosure is not limited thereto. For example, the connection module 70 may be configured such that the outer circumferential surface of the first cylindrical portion 74 and the inner circumferential surface of the second cylindrical portion 76 are in contact with each other. In this case, it is necessary to arrange the second cylindrical portion 76 outside the first cylindrical portion 74. Therefore, the work of attaching the second cylindrical portion 76 needs to be performed in the external space 9, for example.

(6) In the above-described embodiment, the second connection member 72 is divided in the circumferential direction. Additionally, or alternatively, the first connection member 71 may be divided.

Alternatively, neither the first connection member 71 nor the second connection member 72 may be divided. In this case, for example, a gap between the inner circumferential surface 74a of the first cylindrical portion 74 and the outer circumferential surface 76a of the second cylindrical portion 76 needs to be made slightly larger to insert the second cylindrical portion 76 inside the first cylindrical portion 74. In such a configuration, by providing a packing (not shown) between the inner circumferential surface 74a and the outer circumferential surface 76a, high sealability of the EFEM 1 may be obtained while increasing cost of each member. In this case, the internal space 20 of the EFEM 1 may be filled with an inert gas such as nitrogen gas or the like instead of an air. In this case, in order to reduce the cost of the inert gas, it is preferable that the above-mentioned circulation duct 24 is provided.

(7) In the above-described embodiment, the second cylindrical portion 76 partially overlaps with the first cylindrical portion 74 in the front-rear direction. However, the present disclosure is not limited thereto. For example, the first cylindrical portion 74 and the second cylindrical portion 76 may be configured such that the entire first cylindrical portion 74 in the front-rear direction fits within the range in which the second cylindrical portion 76 extends in the front-rear direction. That is, one of the first cylindrical portion 74 and the second cylindrical portion 76 may completely overlap with the other in the front-rear direction.

(8) In the above-described embodiment, the first connection member 71 and the second connection member 72 are screw-fixed to another member. However, the present disclosure is not limited thereto. At least one selected from the group of the first connection member 71 and the second connection member 72 may be fixed to another member by, for example, a clamp (not shown). In this case, the at least one selected from the group of the first connection member 71 and the second connection member 72 may be formed of a member made of a material other than metal, instead of the sheet metal or the thick plate.

(9) In the above-described embodiment, the load lock chamber 7 maintained at an atmospheric pressure close to vacuum corresponds to the front chamber of the present disclosure. However, the present disclosure is not limited thereto. The connection module 70 may be connected to, for example, a chamber (not shown) maintained at substantially the same atmospheric pressure as the transfer chamber 21. In this case, the chamber corresponds to the front chamber of the present disclosure.

(10) In the above-described embodiment, the wafer W is transferred within the transfer chamber 21. However, the present disclosure is not limited thereto. Objects (processing objects) other than the wafer W may be transferred within the transfer chamber 21.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An EFEM comprising:
a housing including a transfer chamber in which a processing object is transferred; and
a connection module provided between the transfer chamber and a front chamber of a processing apparatus configured to perform a predetermined process on the processing object, and configured to connect the transfer chamber and the front chamber,
wherein the housing includes a rear member formed with a housing side opening through which the processing object is capable of passing,
wherein the connection module includes:
a first connection member arranged around the housing side opening when viewed from a depth direction in which the housing and the front chamber are arranged, and attached to the rear member; and
a second connection member arranged around a front chamber side opening formed in the front chamber so as to allow the processing object to pass therethrough when viewed from the depth direction, and attached to the front chamber,
wherein the first connection member includes a first cylindrical portion extending in the depth direction, and
wherein the second connection member includes a second cylindrical portion extending in the depth direction, the second cylindrical portion being arranged to at least partially overlap with the first cylindrical portion in the depth direction and configured to be position-adjustable in the depth direction along the first cylindrical portion.

2. The EFEM of claim 1, wherein the first connection member includes a flange portion attached to the rear member and configured to be position-adjustable with respect to the rear member in a direction in which the rear member extends.

3. The EFEM of claim 1, wherein the rear member includes a first rear member whose position is fixed with respect to the housing, and includes a second rear member attached to the first rear member and to which the first connection member is attached, and
wherein the second rear member is configured to be position-adjustable with respect to the first rear member in a direction in which the first rear member extends.

4. The EFEM of claim 2, wherein the rear member includes a first rear member whose position is fixed with respect to the housing, and includes a second rear member attached to the first rear member and to which the first connection member is attached, and
wherein the second rear member is configured to be position-adjustable with respect to the first rear member in a direction in which the first rear member extends.

5. The EFEM of claim 1, wherein at least one selected from the group of the first connection member and the second connection member is divided into four or more connectable connection pieces in a circumferential direction of the first cylindrical portion and the second cylindrical portion.

6. The EFEM of claim 2, wherein at least one selected from the group of the first connection member and the second connection member is divided into four or more connectable connection pieces in a circumferential direction of the first cylindrical portion and the second cylindrical portion.

7. The EFEM of claim 5, wherein the first cylindrical portion and the second cylindrical portion are in direct contact with each other.

8. The EFEM of claim 6, wherein the first cylindrical portion and the second cylindrical portion are in direct contact with each other.
